(19) United States
(12) Patent Application Publication
(10) Pub. No.: US 2009/0219033 A1
(43) Pub. Date: Sep. 3, 2009

(54) Device for triggering an electromagnetic actuator and method for testing a first inductor of an electromagenetic actuator

(76) Inventors: Hartmut Schumacher, Freiberg (DE); Thomas Kottke, Ehningen (DE); Jens Wirth, Abstatt (DE)

Correspondence Address: KENYON & KENYON LLP, ONE BROADWAY, NEW YORK, NY, 10004, US

(21) Appl. No.: 11/988,701

(22) PCT Filed: Jun. 14, 2006
(86) PCT No.: PCT/EP2006/063182

§ 371 Date: Jan. 12, 2009

(30) Foreign Application Priority Data
Jul. 13, 2005 (DE) 102005033151.3

(51) Int. Cl. G01R 31/28

(52) U.S. Cl. 324/546

(57) ABSTRACT

In a device for triggering an electromagnetic actuator and a method for testing an inductor of an electromagnetic actuator, the inductor is connected to a test circuit in such a way that a resonant circuit is created, and an evaluation circuit is provided that evaluates at least one electrical parameter of this resonant circuit to determine whether the inductance lies within predefined tolerances.

### BACKGROUND OF THE INVENTION

1. Field of the Invention

The present invention relates to a device for triggering an electromagnetic actuator and a method for testing a first inductor of an electromagnetic actuator.

2. Description of Related Art

From Mike Schönmehl: The Crash-Active Headrest, ATZ 5/2005, volume 107, pages 390 to 397, it is known that a crash-active headrest is triggered by an electromagnetic actuator and in particular by a coil, that is, an inductor, in the event of a crash.

### A BRIEF SUMMARY OF THE INVENTION

The device according to the present invention for triggering an electromagnetic actuator and the method for testing a first inductor of an electromagnetic actuator have the advantage that the inductor is monitored or tested by a resonant circuit and therefore a more exact determination of inductance is possible and a better monitoring of the electromagnetic actuator is achieved. By activating a resonant circuit and determining its frequency, it is possible to precisely characterize the inductance. If the inductance corresponds to predefined parameters, the frequency of the resonant circuit lies within predetermined tolerances. In the event of a defect of the inductor, for example, due to a reduced inductance or due to a short circuit between windings of a coil, the frequency of the resonant circuit lies accordingly outside of these tolerances. Then a malfunction is detected, and this is communicated to the driver. A notification to a remote maintenance unit is also possible in this instance. In addition, this measuring result may then be saved permanently to a memory such as an error memory or a crash recorder. This is particularly useful for proving a function of the actuator.

The present invention is thus based on the idea that an inductance may be characterized particularly precisely as a component of a resonant circuit if the other parameters of the remaining components of the resonant circuit are known.

It is particularly advantageous that the test circuit, which is linked to the inductor in such a way that the resonant circuit is formed, has for this purpose a capacitor that is connected in parallel to a switch that itself is connected in series to the inductor. This switch may advantageously be a low-side or a so-called high-side switch, that is, the two power switches that are connected when the inductor is to be supplied with current to trigger the actuator. These switches are thus usually switched through when triggering occurs. These are, for example, power transistors, in particular MOSFET power transistors. However, it is possible for the switch to be the high-side switch, which lies between the inductor and the supply voltage, while the low-side switch lies between the inductor and the ground. Through the parallel connection of the capacitor to the switch, it is later possible to open the switch during monitoring or testing so that the capacitor then becomes a part of the overall circuit and may form the resonant circuit with the inductor. Furthermore, it is advantageous that parallel to this capacitor, a Zener diode is provided to which the evaluation circuit is then linked to measure the voltage in the resonant circuit. The Zener diode additionally fulfills the function of breaking at excessively high voltages in order to protect in particular the switch, that is the power switch, from such overvoltages. Alternatively, it is possible for a capacitor to be directly connected in parallel to the inductor. In this instance, a charge must then be provided for the capacitor.

Multiple configurations are possible for the measurement of inductance by means of a resonant circuit. In a first configuration, a test switch is provided advantageously in parallel to the inductor and to the switch, which test switch is closed during testing so that the inductor together with the connected capacitor and the line, which the test switch has switched through, may form a resonant circuit. When two power switches are used, that is, a high-side and a low-side switch, the test switch is connected in parallel to this entire configuration. However, if only one switch is used, the test switch is connected in parallel to this switch and to the inductor. In addition to these two power switches, it is also possible to provide one main switch when multiple actuators are connected. This allows for increased safety. Both of these power switches may be disposed on a shared substrate. However, it is also possible to dispose them on separate substrates. These possible combinations exist too in the case of one possible main switch. Furthermore, it is possible to also provide a second test switch that, in the case of an open high-side switch, is connected in parallel to the high-side switch, and that connects the resonant circuit to the energy supply, that is, for example, the battery voltage or an energy reserve, and in this way enables the charging of the capacitor so that the resonant circuit may be supplied with energy and the second switch is then also closed again after the capacitor has been charged. This voltage that is used for charging must not be so high, however, that the actuator can be triggered. For this reason, the voltage that is present on this second test switch is lower than the voltage that is supplied directly by the energy reserve, that is, only 5V instead of 40V. If the energy used to charge the resonant circuit is taken from the energy reserve, preferably from a capacitor, the voltage must be converted downward, most easily by a voltage divider.

In an additional configuration, it is possible, when two inductors exist for two actuators, to monitor these together in a simpler circuit. For this purpose, no test switches are required and the two inductors and the corresponding capacitors form together a resonant circuit. In this case, however, the evaluation is more difficult since in the case of error it is determined only that at least one of the inductors is faulty, but not which one. On the other hand, this is a simple circuit and may in many cases be sufficient since a visit to the repair shop is required even when only one inductor fails.

Times of the maxima may be advantageously used as electric parameters and compared with predefined values, or the frequency is evaluated, which may also be determined using maxima, or using zero crossings, or using predefined increasing or decreasing edges.

To capture in an advantageous way the tolerances of a capacitor, in a first step of a test procedure, for example in the first 10 milliseconds, the discharging behavior of the capacitor may be monitored. It is also possible to monitor the charging behavior of the capacitor and from this behavior to determine the capacitance of the capacitor. Then this measured capacitance value may be used to more precisely determine the frequency of the resonant circuit and thus also the inductance by using the Thomson oscillation formula.

Ultimately it is also advantageous that a reference potential is provided that acts as an auxiliary voltage source and charges the resonant circuit with energy. The test circuit may be configured in such a way that the resonant circuit with its oscillation oscillates around this reference potential.

### A BRIEF DESCRIPTION OF THE SEVERAL VIEWS OF THE DRAWING

FIG. 1 shows a block diagram of an example embodiment of the device according to the present invention.

FIG. 2 shows a first circuit diagram illustrating an example embodiment of the device according to the present invention.

FIG. 3 shows a second circuit diagram illustrating an example embodiment of the device according to the present invention.

FIG. 4 shows a third circuit diagram illustrating an example embodiment of the device according to the present invention.

FIG. 5 shows a flow chart illustrating an example method according to the present invention.

FIG. 6 shows a first voltage-time diagram.

FIG. 7 shows a second voltage diagram.

FIG. 8 shows a third circuit diagram illustrating an example embodiment of the device according to the present invention.

### DETAILED DESCRIPTION OF THE INVENTION

Crash-active headrests are increasingly being built into vehicles. These crash-active headrests have the purpose of providing more effective protection against injuries to the cervical spine, such as those that can occur in a rear-end collision, and in this way to minimize personal injury.

In order to be able to correctly use the crash-active headrest, which is triggered by an inductor, that is, a coil, over the entire service life of the application, it is necessary to monitor this inductor. To this end, according to the present invention, this inductor is used to form a resonant circuit, and on the basis of electric parameters of the resonant circuit a determination is made as to whether the inductance lies within predefined tolerances. The measurement or the characterization of a resonant circuit is extremely precise and simple. In addition to crash-active headrests, actuators of a pedestrian protection system can also be triggered electromagnetically. This generally relates to locking and unlocking systems for personal protective means and also rollover bars.

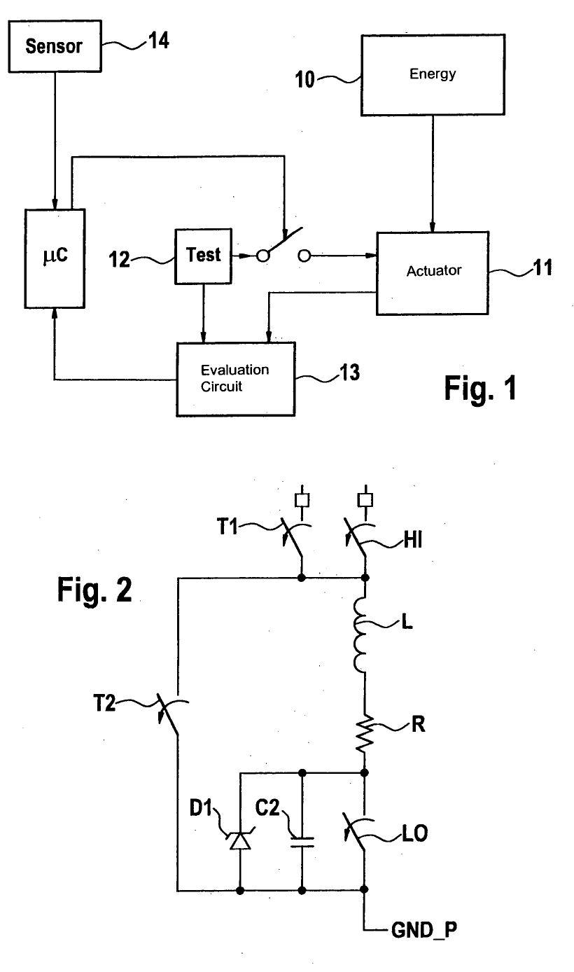

FIG. 1 shows the device according to the present invention in a block diagram. The actuator is represented by block 11. When triggered, the actuator is provided with energy by block 10. According to the present invention, in the case of monitoring, which may be performed periodically, for example, every hour or also at far shorter time intervals, a connection is established to a test circuit 12 in order to determine through the evaluation circuit 13 whether the actuator 11 lies within predefined parameters.

The connection of test circuit 12 to actuator 11 in order to form, in accordance with the present invention, the resonant circuit with the inductor of actuator 11 is achieved by a microcontroller μC via a switch that is also connected to evaluation circuit 13 and actuator 11 to check the parameters in order to see whether they fall within predefined tolerances. At least one switching element is to be provided that ensures that the resonant circuit is provided with energy. This energy may be taken from the energy reserve of the control unit or from the battery voltage. The energy must be regulated in such a way that a triggering of actuator 11 is avoided, for example by a downwards conversion or a current limitation that may be achieved by a current mirror.

In the simplest case, evaluation circuit 13 may be a series resistor that is connected directly to an analog-to-digital input of microcontroller μC. It is, however, possible for the evaluation circuit to be more complex, for example, and for itself to contain the analog-to-digital converter and perhaps additional evaluation components. Microcontroller μC is additionally connected to a sensor 14 to enable the triggering of actuator 11 as a function of this sensor signal. Sensor 40 may be an acceleration sensor system, a surround field sensor system, or combinations of acceleration and surround field sensor systems, and even a contact sensor system may be provided additionally or alternatively. For the sake of simplicity, the circuit according to FIG. 1 is simplified in the drawing so that not all components that are required for the complete operation of the device for triggering actuator 11 are shown. Here, the focus is only on the monitoring of actuator 11.

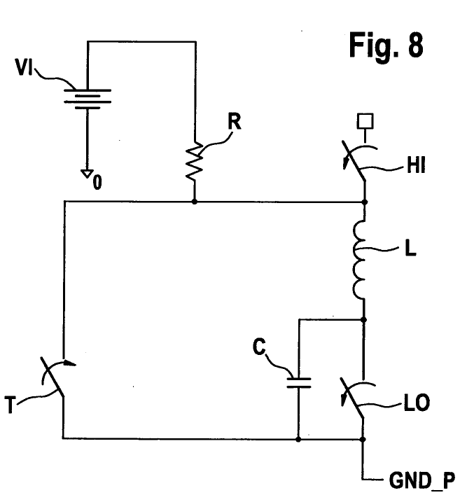

FIG. 8 shows a first embodiment of the device according to the present invention. A power supply VT is connected as a voltage source to a series resistor R_Test and on the other side to ground. Series resistor R_Test is connected on the other side to a test switch T, a high-side switch HI, and a coil L. High-side switch HI is a power switch that is connected to an energy reserve or another energy source. If high-side switch HI switches through, this energy is used to supply the coil and actuator 11 is triggered. Power supply VT is, however, regulated by series resistor R_Test in such a way that it does not trigger the actuator but merely charges the resonant circuit. Here, coil L is a real coil, that is, exhibiting energy loss due to the volume resistance.

The coil is connected on the other side to a capacitor C and a low-side switch that, on their other sides, are connected to ground. Test switch T, too, is connected on the other side to ground.

In the test case, the switch LO is opened so that capacitor C is connected in series to coil L. After a predefined time period or as determined by measurement, test switch T is closed because by then capacitor C is charged and thereby the resonant circuit too. On the basis of the now resulting oscillation, the coil is tested by determining the frequency of the resonant circuit, because the Thomson oscillation formula can determine the inductance of coil L from the frequency and the known capacitance of capacitor C.

FIG. 2 now shows a second specific embodiment of the device according to the present invention. A high-side switch HI is connected on one side to a voltage supply and on the other side to coil L, a test switch T1, and a test switch T2. Test switch T1 is connected on the other side also to the voltage supply or to an auxiliary voltage supply. Test switch T2 is, however, connected on the other side to ground or a diode D, capacitor C, and low-side switch LO. Coil L is connected on the other side to a resistance R that is meant to represent the ohmic resistance of coil L, that is, coil L represents an ideal inductor. Resistance R of the coil is connected on the other side to the other side of diode D, the other side of capacitor C, and the other side of low-side switch LO. At this point, in the test case, the signal to be evaluated may be tapped.

In the test case, high-side switch HI is first open, test switch T1 closed, and test switch T2 open. Low-side switch LO is also open. Capacitor C may be charged through the connection of the supply voltage via test switch T1, via a coil R, and resistance R to capacitor C. After a predefined time, test switch T1 is opened and test switch T2 closed. Alternatively, it is possible to open test switch T1 when the charging voltage is sufficient. Accordingly, a control may be provided.

As a result, a resonant circuit is now formed from coil L, capacitor C, and resistance R, and oscillations occur. These oscillations, which may be tapped via any component of the resonant circuit, are measured primarily via diode D, which takes the form of a Zener diode, and supplied to evaluation circuit 13. These oscillations may be used to measure the frequency of the resonant circuit. The inductance L of the coil may be determined from the frequency, via the known value of the capacitance of capacitor C. Resistance R causes merely the attenuation of the oscillations and has only a small influence on the frequency of the resonant circuit that may be determined using the known Thomson oscillation formula. The value of inductance L is then compared by evaluation circuit 13 and microcontroller μC with predefined values in order to determine whether inductance L still lies within predefined tolerances. If inductance L lies outside of predefined tolerances, this is displayed to the driver, in order to prompt a visit to the workshop.

Test switch T1 is necessary here so that high-side switch H1 is not loaded with the high voltage of the energy reserve in such a way that the maximum allowable non-breaking current is exceeded and that the energy content of coil L would become too high and the negative amplitude of the oscillation could extend too far below the ground potential so that the function of microcontroller μC could be disturbed, the positive amplitude possibly going beyond the allowed positive voltage at the input of an analog-digital converter of the evaluation circuit.

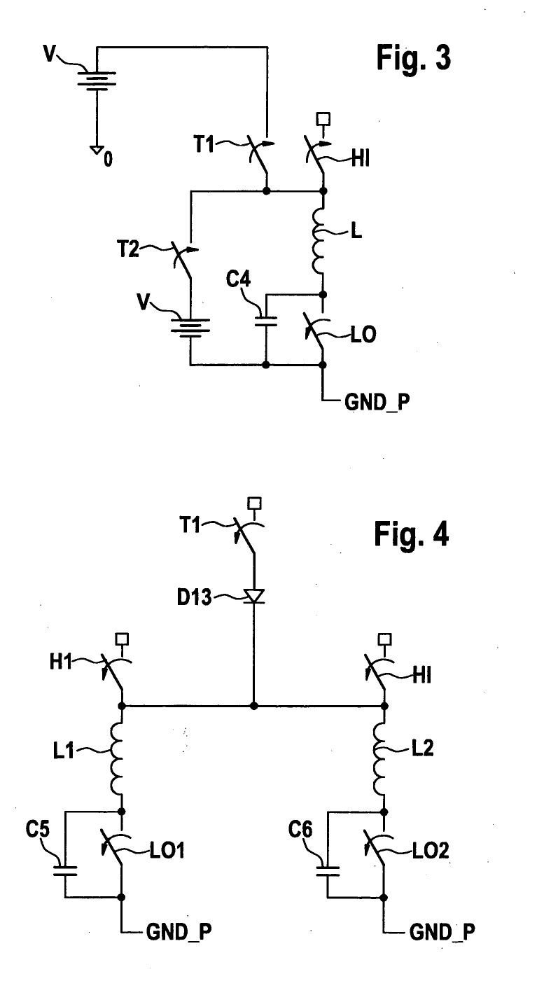

FIG. 3 explains in an additional circuit example an extension of the circuit according to FIG. 2. Here, identical components are labeled with the same reference symbols. In addition, a reference potential V to ground is provided in series to test switch T2, which reference potential raises the reference point to a potential that is easy to evaluate. Here, a value of 1.93 volts was chosen; however, depending on the specific application, other values are possible as well. The reference potential is provided by a voltage regulator that normally exists as an ASIC or part of an ASIC in the control unit.

This increase makes it possible to evaluate the frequency via digital gates, a counter, or a HET (High End Timer). The HET is a counter that measures the zero crossings within a particular time period.

FIG. 4 shows an additional variant of an embodiment of the present invention. Here, two actuator coils L1 and L2 are connected in parallel to each other. Two high-side switches H1 and H2 are each connected to each other on the one side and connected via a reverse-polarity protection diode that is not shown here to the supply voltage. On the other side, high-side switch H1 is connected to coil L1 that is connected on the other side with a capacitor C5 and low-side switch LO1. Low-side switch LO1 is connected on the other side, like capacitor C5, to ground. High-side switch H2 is connected on the other side to coil L2 that is connected on the other side to capacitor C6 and low-side switch LO2. Low-side switch LO2 is connected on the other side, like capacitor C6, to ground. Furthermore, a test switch T1 is provided that connects an energy supply so that capacitors C5 and C6 may be charged. Test switch T1 is connected via a diode D13 to coils L1 and L2 as well as high-side switches H1 and H2.

In the test case, high-side switches H1 and H2 remain open and test switch T1 is closed in order to supply capacitors C5 and C6 with energy.

Low-side switches LO1 and LO2 remain open, as is the case during the charging operation, so that capacitor C5 and capacitor C6 each lie in series to coils L1 and L2 and are charged. Actuator coils L1 and L2 and capacitors C5 and C6 then form a resonant circuit. The oscillation frequency then does not correspond to a predefined value if coils L1 and L2 differ in terms of inductance.

If the voltage is measured, for example, via Zener diodes, not shown here, a voltage curve is obtained that has an oscillatory characteristic having a damping. This may also be obtained by every other component of the resonant circuit. For evaluating the inductances, the time of the first maximum is determined. If the maximum lies outside of a specific tolerance limit, it must be assumed that one of the two coils is defective. Furthermore, it is also possible to determine the frequency by determining the time interval between two maxima. Based on this, the Thomson oscillation formula may then be used, as explained above, to calculate the inductance.

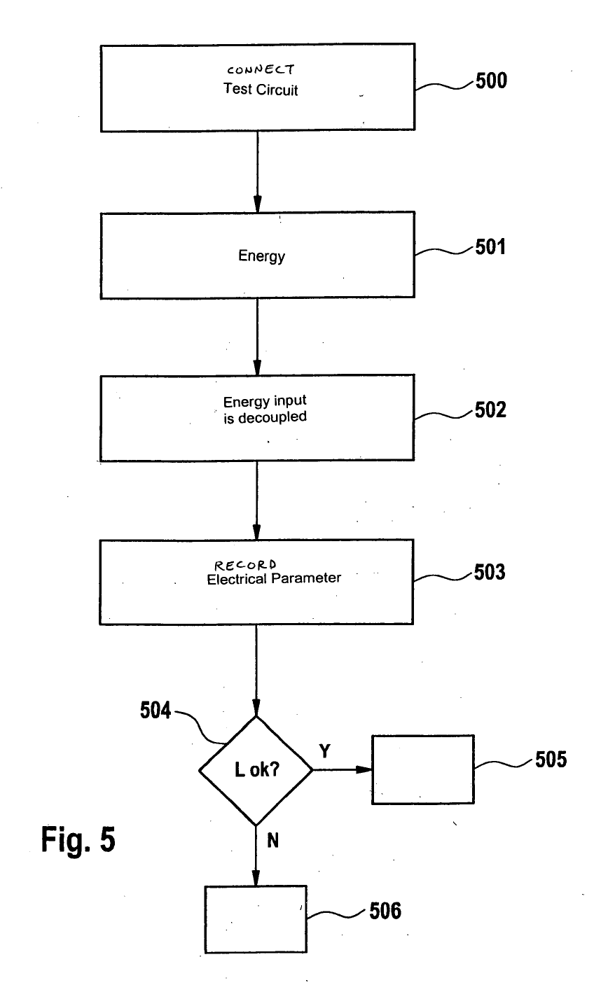

FIG. 5 is a flow chart showing the method according to the present invention. In method step 500, the test circuit is connected to form the resonant circuit. However, before the resonant circuit can begin to oscillate, it must be supplied with energy, which is done in method step 501. To this end, the capacitor is charged. This charging operation may be monitored to determine the capacitance of the capacitor. This makes the subsequent determination of the inductance more precise. In this method, the capacitance of the capacitor is determined first in the time period, for example from 0 to 10 milliseconds, namely, via its charging curve. The discharging curve may also be used for this purpose, however. On the basis of the determination of the capacitance, this value may then be taken into account for the calculation for the inductance of the coil that, starting from the time, for example, of 20 milliseconds, is determined on the basis of the resonant circuit frequency. The capacitance of the capacitor may be determined with the aid of the measurement of the discharging or charging voltage at two points in time via the known formula τ=R*C.

In method step 502, the energy input is decoupled and the side of the inductor that is connected to the high-side switch is connected to the reference potential or to ground. During oscillation of the resonant circuit, the relevant electrical parameter or parameters that are characteristic for the resonant circuit are recorded in method step 503. The frequency is characteristic for the resonant circuit. This is calculated from the inductance and the capacitance of the resonant circuit. The damping also has a minor influence. Either the period between two maxima may be used, for example, for determining the frequency, or a timer is started at a zero crossing, is stopped at the next zero crossing, the time period is measured, and the period or the frequency is determined according to the number of zero crossings. It is also possible to use the time period between only two zero crossings to determine the frequency. To eliminate a possible zero-frequency quantity of the voltage to be measured, a capacitor may be inserted between the quantity to be measured and the evaluation circuit.

If the inductance can be determined by the parameters of the resonant circuit, then a check is performed in method step 504 to see whether the inductance corresponds to predefined tolerances. If this is the case, then the system waits in method step 505 until the next test cycle can be run. If this is not the case, then this error is signaled to the driver in method step 506. The signaling may be done via the on-board computer, via lamps in the instrument panel, via voice output, or via a head-up display. An automatic transmission to a remote maintenance unit is also possible. In addition, it is possible to store this result in a memory to make it available for a later evaluation.

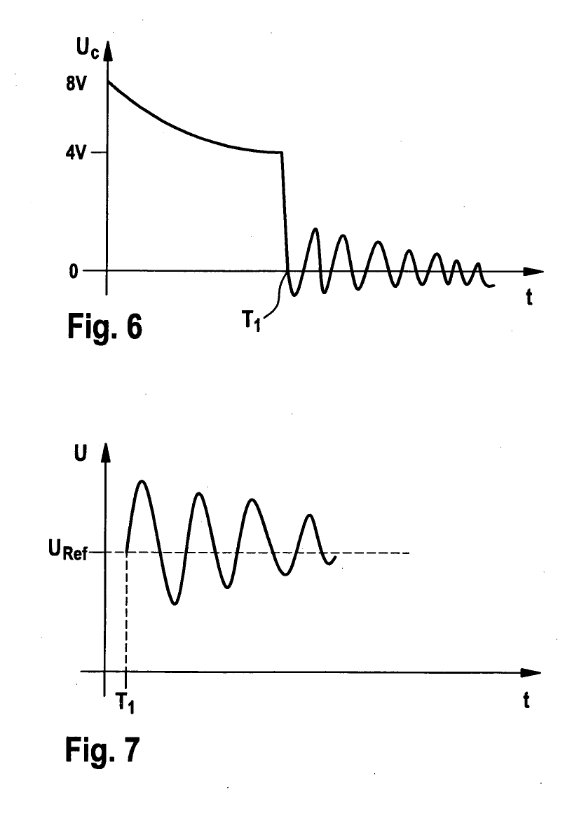

In a first time period until T₁ according to FIG. 6 or FIG. 7, the capacitor is charged. For this purpose, the voltage falls from 8 volts to 4 volts, as shown in FIG. 6. Starting at T₁, the oscillations set in, which run periodically and are dampened due to coil resistance R and therefore die down in amplitude according to an e-function. In FIG. 6, the oscillation runs around the ground potential; in FIG. 7 around the potential Uref of the reference voltage.

1-17. (canceled)

18. A device for controlling an electromagnetic actuator having a first inductor, wherein the first inductor is supplied with current in the case of triggering of the actuator by the device, the device comprising:
a test circuit connected to the first inductor, wherein the test circuit is configured to monitor the first inductor and form a resonant circuit together with the first inductor; and
an evaluation circuit configured to record at least one electrical parameter of the resonant circuit and determine, as a function of the at least one electrical parameter, whether the first inductor enables the triggering of the actuator when supplied with current.

19. The device as recited in claim 18, wherein the test circuit has at least one first capacitor configured to form a resonant circuit connected in parallel to a first switch, and wherein the first switch is connected in series to the first inductor.

20. The device as recited in claim 19, wherein a first Zener diode is provided in parallel to the at least one first capacitor, and wherein the evaluation circuit is coupled to the first Zener diode.

21. The device as recited in claim 19, wherein the first switch is configured as a first low-side switch.

22. The device as recited in claim 21, wherein the device has a first test switch connected in parallel to the first inductor, the first switch, and the at least one first capacitor, and wherein the first test switch is closed for forming the resonant circuit.

23. The device as recited in claim 22, wherein a second test switch connected between an energy supply and the first inductor is provided.

24. The device as recited in claim 19, wherein a second inductor and a second switch are connected in series with one another, and wherein the second inductor and a second switch are connected in parallel to the first inductor and the first switch, and wherein a second capacitor is connected in parallel to the second switch.

25. The device as recited in claim 19, wherein a reference potential is provided that serves to charge the resonant circuit.

26. The device as recited in claim 25, wherein the test circuit is configured to enable the resonant circuit to oscillate around the reference potential.

27. The device as recited in claim 24, wherein a second Zener diode is connected in parallel to the second capacitor.

28. A method for testing a first inductor of an electromagnetic actuator, comprising:
connecting a test circuit to the first inductor for forming a resonant circuit;
supplying the resonant circuit with energy;
recording, by an evaluation circuit, at least one electrical parameter of the resonant circuit; and
testing, based on the at least one electrical parameter, whether the first inductor enables a triggering of the actuator.

29. The method as recited in claim 28, wherein an initial maximum of an oscillation of the resonant circuit is used as the at least one electrical parameter, and wherein the time of the initial maximum is compared with a predetermined tolerance range.

30. The method as recited in claim 28, wherein the frequency of the resonant circuit is used as the at least one electrical parameter.

31. The method as recited in claim 30, wherein the frequency of the resonant circuit is determined by ascertaining one of: a) consecutive maxima; b) consecutive zero crossings; c) consecutive rising edges at predefined voltage values; or d) consecutive falling edges at predefined voltage values.

32. The method as recited in claim 30, wherein in a first time period, one of a charging or discharging behavior of a first capacitor of the resonant circuit is determined, and wherein the capacitance of the first capacitor is determined based on the one of the charging or discharging behavior, and wherein the capacitance of the first capacitor is used together with the frequency of the resonant circuit for determining the inductance of the first inductor.

33. The method as recited in claim 28, wherein a first test switch connected in parallel to the first inductor is closed, after energy is supplied, to form the resonant circuit.

34. The method as recited in claim 28, wherein a second inductor is provided in parallel to the first inductor, and wherein the second inductor is connected to the test circuit to form the resonant circuit such that the first and second inductors are tested together.
